(19) United States
(12) Patent Application Publication
(10) Pub. No.: US 2004/0125581 A1
(43) Pub. Date: Jul. 1, 2004

(54) Device and method for selectively modifying a backplane

(75) Inventors: Dan Kesner Carter, Broken Arrow, OK (US); Daniel Robert Carroll, Allen, TX (US); Kevin Randall Smith, Allen, TX (US); Thomas Gray Leete, Plano, TX (US)

Correspondence Address: HAYNES AND BOONE, LLP, 901 MAIN STREET, SUITE 3100, DALLAS, TX, 75202, US

(73) Assignee: TelStrat International, Ltd., Plano, TX (US)

(21) Appl. No.: 10/663,627

(22) Filed: Sep. 16, 2003

Related U.S. Application Data
(60) Provisional application No. 60/319,553, filed on Sep. 16, 2002.

(51) Int. Cl. H05K 7/14; H05K 7/18

(52) U.S. Cl. 361/796

(57) ABSTRACT

Provided is a module for attachment to an existing backplane in a telecommunications system. In one example, the module provides high speed interconnect paths for transporting large quantities of data flowing through the system, while enabling the existing backplane to carry lower bandwidth power and control functions. The module may be easily added to a unit in the field without disturbing the operation of the system. In another example, the module may be used to provide the existing backplane with additional functionality, alternate connection types, or other modifications.

### CROSS-REFERENCE

The present application claims priority from U.S. Provisional Patent Application Ser. No. 60/319,553, filed on Sep. 16, 2003.

### BACKGROUND

The present disclosure relates generally to telecommunications devices and, more particularly, to a device and method for selectively modifying a backplane.

Telecommunications equipment provides for the transport of data between two or more locations. The data transported by telecommunication systems in the past has been primarily voice data for telephone conversations. Voice data typically requires 64 thousand bits per second (KBPS) for each side of a voice call. Technological advances in telecommunications such as data modems and Asymmetric Digital Subscriber Line (ADSL) have increased the quantity of data and the rate data is to be transferred between locations. The transported data may now represent many types of information, such as computer file data, video data streams, fax data streams, and voice data. Data rates supplied to business and residential subscribers may exceed one million bits per second (1 MBPS) and can reach into the hundreds of MBPS.

The telecommunication systems are typically constructed of a number of printed circuit daughter boards, each of which is connected to a backplane. A number of different types of daughter boards are typically attached to the backplane. Some of the daughter boards are used to provide attachment to the subscriber telephone (data) lines. Other daughter boards may provide system control functions, while still others provide connectivity to data path interconnection (switching) elements and global data transport networks. Many types of daughter boards may be found in a given system. The backplane may provide several functions. For example, it may provide a path to supply electrical power to each of the daughter boards. Electrical paths may also be provided to pass control information between the daughter boards. The backplane may also provide paths for passing the data between the subscriber interface boards and the switching elements and network interface ports.

The amount of data that can be passed between the various daughter boards has undergone a steady increase with time. This data transport capacity, or bandwidth, is determined by factors such as the number of electrical paths and the individual bandwidth of each path. Advances in technology have allowed the aggregate bandwidth of the backplanes to steadily increase. However, a difficulty with telecommunication systems has historically been that backplanes embedded in the systems are ultimately limited in their useful lifetime by the bandwidth restrictions implicit in the technology used in their construction. One solution is to design systems with excessive bandwidth backplanes to extend their useful lifetime. However, this approach is costly and may result in prohibitive initial system costs. This approach also fails to address new technologies that may not exist or may not be practical to implement when a backplane is designed and embedded.

Accordingly, what is needed is a system and method for modifying a backplane in a modular manner.

### SUMMARY

In one embodiment, a system is provided having a modifiable backplane capability. The system comprises a chassis, an embedded backplane, and a replaceable module. The embedded backplane is positioned within the chassis and adapted to receive a plurality of daughter boards. The replaceable module is positioned proximate to the embedded backplane and adapted to receive the daughter boards, wherein the system is modifiable depending on a selected characteristic of the replaceable module.

### BRIEF DESCRIPTION OF THE DRAWINGS

FIG. 1 illustrates a conventional telecommunications system.

FIG. 2 illustrates one method of connecting a replaceable modular backplane to the system illustrated in FIG. 1.

FIG. 3 illustrates the use of a daughter card with the replaceable module of FIG. 2 and the system of FIG. 1.

FIG. 4 illustrates exemplary data paths that may be provided in the replaceable module of FIGS. 2 and 3.

FIG. 5 is a flow chart of an exemplary method for replacing a removable backplane.

### WRITTEN DESCRIPTION

The present disclosure relates generally to telecommunications devices and, more particularly, to a device and method for selectively modifying a backplane. It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

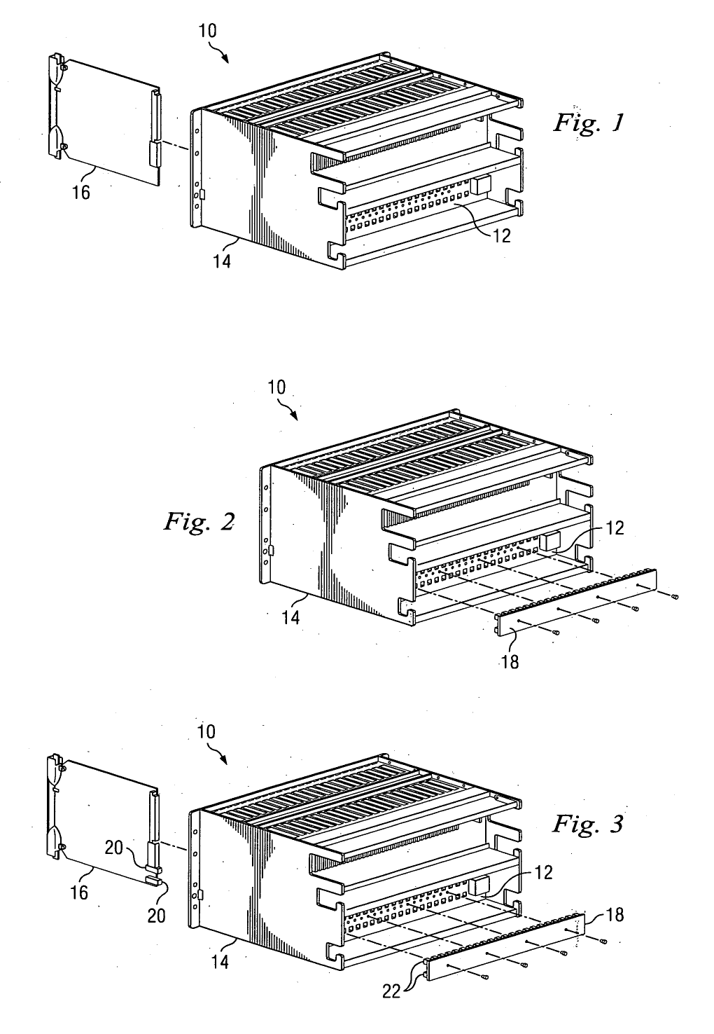

FIG. 1 illustrates one embodiment of a system 10 that may be used in a telecommunications system (not shown). The system 10 includes a system backplane 12 that is affixed to a chassis 14 (e.g., a housing) as an embedded component. One or more daughter boards 16 may be connected to the system backplane 12. The system backplane 12 is typically intended to serve for the life of the system 10. Accordingly, bandwidth restrictions caused by the design of the system backplane 12 are a permanent limitation of the system 10. Because the system backplane 12 is affixed to the chassis 14, replacing the system backplane 12 in such a system requires the complete disassembly and reassembly of the entire system 10. This is undesirable in the telecommunications field because subscribers serviced by the system 10 may be without communications services for the duration of the backplane replacement operation.

Referring now to FIG. 2, in one embodiment, a replaceable module 18 is illustrated. The module 18 is capable of simple attachment to the existing system backplane 12 using screws, latches, quick detach mechanisms, an interference fit, or other suitable means. The replaceable module 18 provides high speed interconnect paths needed for transporting large quantities of data flowing through the system 10. The existing system backplane 12 may continue to carry lower bandwidth power and control functions. The replaceable module 18 may be easily added to a unit in the field without disturbing the operation of the system 10. Furthermore, daughter boards (such as the daughter board 16 of FIG. 1) that are capable of communicating via the replacement module 18 may utilize the high speed interconnect paths for data transport. Accordingly, the replaceable module 18 provides a number of features. For example, one feature is an ability to upgrade the replaceable module 18 in the field easily and quickly. A second feature provided by the replaceable module 18 is that additional bandwidth may be added as needed by system capability expansion or by increases in composite subscriber bandwidth. In addition, new technologies may be incorporated into the replaceable module 18 as they become available to extend system capabilities and or reduce system costs. This capability may be used to extend the useful lifetime of the system 10 and thus reduce the cost of ownership.

Referring now to FIG. 3, the replaceable module 18 is shown ready for attachment to the system 10 with a daughter board 16 positioned for connection to the combination of the system backplane 12 and the replaceable module 18. In the present example, the daughter board 16 has a connection mechanism 20 that extends through the system backplane 12 to access a corresponding connection mechanism 22 present on the replaceable module 18. It is understood that many types of connection mechanisms and technologies may be used. For example, electrical connections, optical connections, wireless connections, infrared connections, and/or other existing or future technologies may be utilized to provide connectivity between the daughter boards 16 and the replaceable module 18 to extend the bandwidth and capabilities of the system 10. Furthermore, a variety of alignment mechanisms may be provided to facilitate alignment of the replaceable module 18 within the chassis 14. For example, the replaceable module 18 may be aligned using grooves, markings, or attachment means provided by the chassis 14, or may be aligned using holes or other markings provided by the system backplane 12.

The incorporation of a replaceable module into a system can thus provide for easy field upgrades capable of extending the bandwidth and capabilities of a telecommunications system. This capability may extend the lifetime of the system and provide for more favorable system economy.

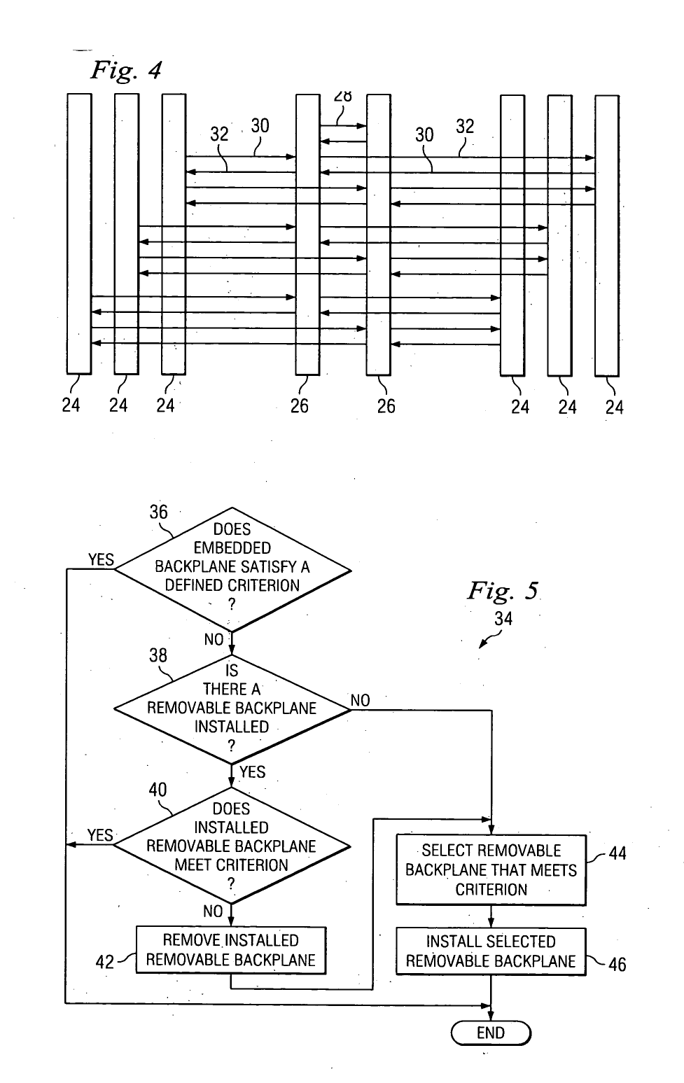

With reference now to FIG. 4 and with continued reference to FIGS. 1-3, another embodiment of the present disclosure is illustrated. In the present example, the chassis 14 is designed to support two backplanes. These are the system backplane 12 (e.g., a general purpose embedded backplane) and the replaceable module 18. It is understood that the term “embedded” includes any manner of affixing or attaching the backplane in a manner that is not easily removable. The general purpose backplane 12 supports up to twenty-two boards and provides paths to distribute several signal groups to the twenty-two board slots. These signal groups (not shown) may include power, master clock distribution, a voice channel highway, and a data channel highway.

The voice channel highway transports low bandwidth digitally encoded voice information. This voice channel highway is shared between all of the slots and provides a total bandwidth of approximately 192 megabits per second of voice traffic throughput. The data channel highway may be a redundant pair of highways that carry data in an Asynchronous Transfer Mode (ATM) format. These redundant data channel highways may also be shared between the twenty-two slots and may provide an aggregate bandwidth of approximately 2.1 gigabits per second of data bandwidth throughput.

In the present example, the voice and data channel highways may be sufficient for carrying a telephone voice call and a moderate amount of data traffic, such as that needed for supplying Digital Subscriber Line (DSL) traffic for end users. However, other systems may need to carry much larger amounts of data traffic, such as digitized video traffic. For these systems, the replaceable module may be attached to provide an additional backplane with added data bandwidth.

Referring particularly to FIG. 4, an exemplary implementation of the replaceable module 18 includes twenty-two slots, with twenty of the slots available for use as general purpose board slots 24 for daughter boards 16 and two of the slots 26 filled with a pair of redundant router boards (not shown). For purposes of clarity, only the two router board slots 26 and six general purpose board slots 24 are illustrated. The router boards include circuitry to perform the necessary data routing functions appropriate to the type of data traffic being carried, and may be connected to each other via signal lines 28.

The replaceable module 18 also provides a plurality of signal lines (e.g., data paths) to carry data traffic to and from each of the general purpose board slots 24 to the pair of redundant router board slots 26. In the present example, each of the general purpose board slots 24 has two pairs of data transfer wires 30 to carry data from that general purpose board slot 24 to each of the router board slots 26, and an additional two pairs 32 from each router board slot 26 to return data from the router board slots 26 to each of the general purpose board slots 24. For purposes of illustration, each of these pairs of wires 30, 32 is capable of carrying 3.125 Gigabits of data. Accordingly, each general purpose board slot 24 may transfer 6.250 Gigabits of data to and from each of the two router board slots 26. The 6.250 Gigabit paths are for the exclusive use of each general purpose board slot 24 to transfer data to and from the redundant router board slots 26. The aggregate bandwidth that can be transported through the exemplary system 10 is thus 6.250×2×20=250 Gigabits per second.

It is noted that the addition of the replaceable module 18 does not interfere with the normal operation of the data and voice channel highways provided by the general purpose backplane 12. Furthermore, each of the slots (of the general purpose backplane 12) may be equipped to access the additional bandwidth made available by the replaceable module 18. In the present example, installing the replaceable module 18 increases the system bandwidth from just over 2 gigabits per second to approximately 250 Gigabits per second. In this manner, future bandwidth requirements may be supported by replacing the replaceable module 18 with other replaceable modules having the desired bandwidth (e.g., 10 Gigabits per second per pair). The system 10 can thus be upgraded to support larger bandwidth traffic requirements with the addition of the replaceable module 18, rather than having to replace the entire system as is the case in many current system architectures.

Referring now to FIG. 5, in yet another embodiment, a method 34 may be used to install a removable module (e.g., a backplane) in the system 10 of FIGS. 1-3. The method 34 begins in step 36 by determining whether a non-removable backplane within the system 10 satisfies at least one defined criterion. For example, the criterion may be that the non-removable backplane 10 provide a certain amount of bandwidth. If the non-removable backplane does satisfy the defined criterion, then the method 34 ends. If the non-removable backplane does not satisfy the defined criterion, the method 34 continues to step 38, where a determination is made as to whether a removable backplane is installed.

If a removable backplane is not installed, the method 34 jumps to step 44, which will be described below. However, if a removable backplane is installed, the method 34 continues to step 40, where a determination is made as to whether the installed removable backplane satisfies the defined criterion. If the installed removable backplane does satisfy the defined criterion, then the method 34 ends. If the installed removable backplane does not satisfy the predetermined criterion, then the method 34 continues to step 42, where the installed removable backplane is removed. In step 44, a removable backplane is selected that meets the defined criterion and, in step 46, the selected removable backplane is installed.

The above disclosure provides many different embodiments, or examples, for implementing different features of the disclosure. Specific examples of components, and processes are described to help clarify the disclosure. For example, while the backplanes described above include up to twenty-two slots, it is understood that more or fewer slots may be used. Furthermore, while the disclosure describes pairs of paths used in data transfer, it is understood that any combination of paths may be used and that the number of paths leading to a router board from a general purposes board may not be equal to the number of paths leading to the general purpose board from the router board. Accordingly, it will be understood by those skilled in the art that various changes in form and detail may be made therein without departing from the spirit and scope of the disclosure.

What is claimed is:

1. A system having a modifiable backplane capability, the system comprising:
a chassis;
an embedded backplane positioned within the chassis and adapted to receive a plurality of daughter boards; and
a replaceable module positioned proximate to the embedded backplane and adapted to receive the daughter boards, wherein the system is modifiable depending on a selected characteristic of the replaceable module.

2. The system of claim 1 wherein the chassis is adapted for receiving both the embedded backplane and the replaceable module.

3. The system of claim 1 wherein the embedded backplane is positioned between the daughter boards and the replaceable module.

4. The system of claim 3 wherein at least one of the daughter boards includes a connector adapted to extend through the embedded backplane and into the replaceable module.

5. The system of claim 3 wherein the embedded backplane includes a plurality of openings, and wherein the replaceable module is configured to receive the daughter boards via the plurality of openings.

6. The system of claim 3 wherein the chassis includes an opening proximate to the embedded backplane for accessing the replaceable module.

7. The system of claim 1 wherein at least one of the daughter boards includes a first connector adapted to connect to the embedded backplane and a second connector adapted to connect to the replaceable module.

8. The system of claim 1 wherein the embedded backplane is in signal communication with the replacement module.

9. The system of claim 1 wherein the replaceable module is a replaceable backplane, and wherein the selected characteristic of the replaceable backplane provides the system with additional bandwidth.

10. The system of claim 1 wherein the replaceable backplane includes a plurality of general purpose slots, wherein each general purpose slot is adapted to receive a daughter board.

11. The system of claim 10 further comprising a router card connected to one of the general purpose slots, wherein router card is adapted to control the flow of data through the replaceable module.

12. The system of claim 11 wherein the replaceable module further includes first and second sets of data transfer paths connecting each general purpose slot and the router card, wherein the first set of data transfer paths is adapted to transfer data from each general purpose slot to the router card, and wherein the second set is configured to transfer data from the router card to each general purpose slot.

13. A replaceable module adapted for modifying at least one characteristic of a telecommunications device having an embedded backplane, the module comprising:
a body portion, wherein the body portion includes a plurality of data paths;
a plurality of connections in communication with the data paths for connecting at least one of the data paths to one or more printed circuit boards; and
alignments means for positioning the module with respect to the backplane.

14. The replaceable module of claim 13 wherein the connections are positioned on the module to correspond to openings in the embedded backplane.

15. The replaceable module of claim 13 further comprising:
a plurality of printed circuit boards in signal communication with the connections; and
at least one router board, wherein the router board is attached to each printed circuit board via at least one data path.

16. The replaceable module of claim 15 wherein the router board is attached to each printed circuit board via first and second data paths, wherein the first data path is adapted to transfer data from the printed circuit board to the router board, and wherein the second data path is adapted to transfer data from the router board to the printed circuit board.

17. The replaceable module of claim 16 wherein the first and second data paths each comprise a pair of signal lines.

18. A method for selectively replacing a removable backplane in a telecommunications device, the method comprising:
identifying that an embedded backplane fails to meet at least one defined criterion;
selecting a removable backplane meeting the defined criterion; and
installing the removable backplane in a position proximate to the embedded backplane, wherein the removable backplane is adapted to provide functionality compatible with the defined criterion.

19. The method of claim 18 further comprising:
identifying that an installed removable backplane fails to meet the at least one defined criterion; and
removing the installed removable backplane from the device prior to installing the removable backplane meeting the defined criterion.

20. The method of claim 18 further comprising aligning slots in the removable backplane with holes in the embedded backplane prior to installing the removable backplane.
